(19) United States
(12) Patent Application Publication
(10) Pub. No.: US 2002/0058427 A1
(43) Pub. Date: May 16, 2002

(54) Electrical card connector for solderlessly electrically connecting to a printed circuit board

(76) Inventor: Hung-Chi Yu, Hsi-Chih (TW)

Correspondence Address: Wei Te (Joseph) Chung, Foxconn International, Inc., 1650 Memorex Drive, Santa Clara, CA, 95050, US

(21) Appl. No.: 09/752,403

(22) Filed: Dec. 27, 2000

(30) Foreign Application Priority Data
Nov. 15, 2000 (TW) 89219740

(51) Int. Cl. H05K 1/00

(52) U.S. Cl. 439/64

(57) ABSTRACT

An electrical card connector for electrically connecting to a printed circuit board (5) includes an insulative housing (1), a plurality of terminals (2, 3), and a fastening device (4). The housing comprises a transverse beam (10) and a pair of arms (11) formed on opposite ends of the transverse beam. A plurality of passageways (12) is defined in the transverse beam. The terminals each have a fixing portion (22, 32) engaging with the passageway, and a touch portion (23, 33) extending beyond a bottom of the transverse beam. When the electrical card connector is fastened to the printed circuit board by the fastening device, the touch portions of the terminals resiliently make electrical contact with corresponding electrical pads (54) mounted on the printed circuit board.

### BACKGROUND OF THE INVENTION

1. Field of the Invention

The present invention relates to an electrical card connector, and particularly to an electrical card connector having terminals electrically connectable to a printed circuit board using solderless means.

2. Description of the Related Art

In the prior art, an electrical card connector has a plurality of terminals electrically connecting to a printed circuit board by one of two means. One means is to directly solder the terminals to the printed circuit board. Using this means, two different soldering technologies are available to achieve an electrical connection between the terminals and the printed circuit board. One soldering technology, through-hole technology, requires insertion of each terminal through a corresponding through hole defined in the printed circuit board. The terminals are then soldered to the printed circuit board. However, the difficulty with this technology is that it is not easy to align each terminal with each corresponding through hole; thus, the alignment operation is inconvenient. Another soldering technology, surface mounting technology (SMT), requires soldering of each terminal to a surface of a solder pad of the printed circuit board. However, this technology requires planarity of all the terminal ends and of all the solder pads on the printed circuit board prior to soldering, which presents its own problems. The other means of connecting the terminals to the printed circuit board is to use an adaptor. With this means, the terminals of the electrical card connector are plugged into the adaptor, which has been previously soldered to the printed circuit board. This means is costly in terms of additional components required and the electric resistance between the printed circuit board and the connector is increased. Thus, the connection process is costly and the connection is less desirable.

Hence, an improved electrical card connector is required to overcome the disadvantages of the prior art.

### BRIEF SUMMARY OF THE INVENTION

A main object of the present invention is to provide an electrical card connector which can be expediently connected to a printed circuit board.

An electrical card connector for electrically connecting an electrical card to a printed circuit board comprises an insulative housing, a plurality of terminals, and a fastening device. The housing comprises a transverse beam and a pair of arms formed on opposite ends of the transverse beam. A plurality of passageways is defined in the transverse beam. The terminals each have a contacting portion at one end thereof for electrically connecting with an electrical card, a fixing portion extending opposite the contacting portion and fixed in a corresponding passageway, and a touch portion extending downwardly from the fixing portion. The touch portion comprises a first section perpendicular to the fixing and contacting portions and a second section parallel to the fixing portion. The second section protrudes in a resilient arc below a bottom face of the housing. The fastening device comprises a pair of screws and nuts. The screws are insertable through a pair of fastening holes defined in both arms of the housing. The electrical card connector is fastened on the printed circuit board by the screws extending through the fastening holes and through a pair of positioning holes defined in the printed circuit board to engage with the nuts. The second sections of the touch portions of the terminals resiliently make electrical contact with corresponding electrical pads mounted on the printed circuit board.

Other objects, advantages and novel features of the invention will become more apparent from the following detailed description of the present embodiment when taken in conjunction with the accompanying drawings.

### BRIEF DESCRIPTION OF THE DRAWINGS

FIG. 1 is an exploded view of an electrical card connector with a printed circuit board in accordance with the present invention;

FIG. 2 is a cross sectional view of the electrical card connector of FIG. 1 taken along line 2-2 of FIG. 1, prior to mounting on the printed circuit board; and

FIG. 3 is a cross sectional view of the electrical card connector mounted on the printed circuit board.

### DETAILED DESCRIPTION OF THE INVENTION

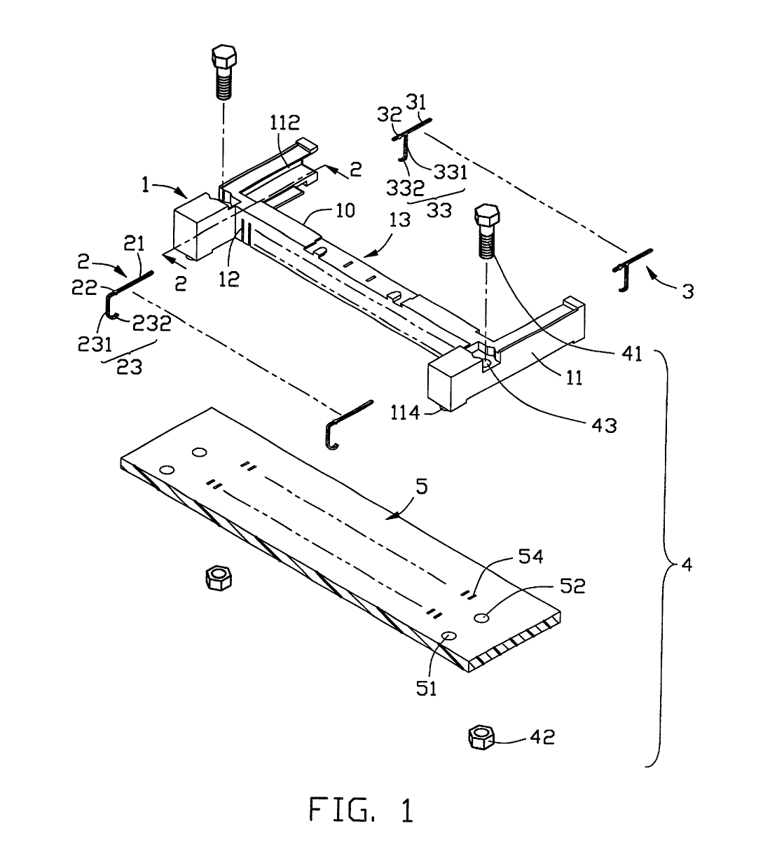

Referring to FIG. 1, an electrical card connector in accordance with the present invention for electrically connecting to a printed circuit board 5 comprises an insulative housing 1, a plurality of first terminals 2, a plurality of second terminals 3, and a fastening device 4.

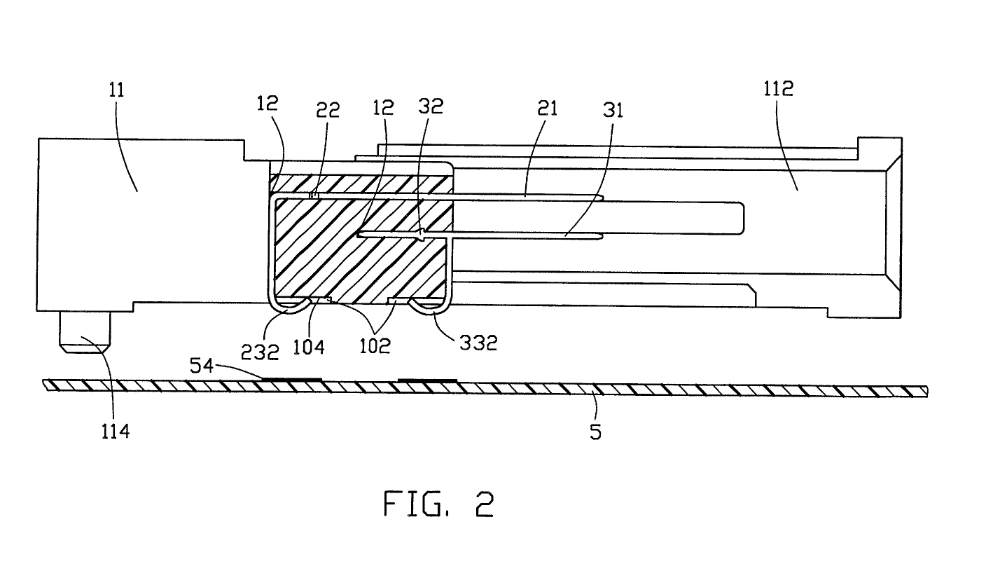

The housing 1 comprises a transverse beam 10 and a pair of arms 11 formed on opposite ends of the transverse beam 10. A receiving space 13 is defined between both arms 11 and the transverse beam 10. A plurality of passageways 12 is defined in the transverse beam 10 and each passageway 12 is parallel to the arms 11. Referring to FIG. 2, a plurality of recesses 102 is defined in a bottom face (not labeled) of the transverse beam 10 and each recess 102 aligns with a corresponding passageway 12. The arms 11 each define a channel 112 communicating with the receiving space 13 for guiding an electrical card (not shown) mating with the electrical card connector. A pair of projections 114 is formed on bottom faces (not labeled) of the arms 11.

Each first terminal 2 has a contacting portion 21 at one end thereof for electrically connecting with the electrical card, a fixing portion 22 at a middle thereof, connecting to the contacting portion 21, and a touch portion 23 at a second end thereof extending downwardly from the fixing portion 22. The touch portion 23 comprises a first section 231 perpendicular to the fixing portion 22 and a second section 232 parallel to the fixing portion 22. Each second terminal 3 comprises a contacting portion 31 at one end thereof, a fixing portion 32 at a second end opposite the contacting portion 31, and a touch portion 33 extending downwardly and perpendicularly to the contacting portion 31 and the fixing portion 32 from a junction of the contacting portion 31 and the fixing portion 32. The touch portion 33 comprises a first section 331 perpendicular to the fixing portion 32 and a second section 332 parallel to the fixing portion 32. The second sections 232, 332 each have an arced shape and are resiliently bendable.

The fastening device 4 comprises a pair of screws 41, and a pair of nuts 42. A pair of fastening holes 43 is correspondingly defined in both arms 11 adjacent to the beam 10 for extension of the screws 41 therethrough.

Referring to FIG. 2, in assembly, the first and second terminals 2, 3 are inserted into the corresponding passageways 12 with the fixing portions 22, 32 being fixed within the passageways 12, the contacting portions 21, 31 extending into the receiving space 13, and the touch portions 23, 33 respectively extending along a front and a rear sides of the transverse beam 10 and partly extending into the recesses 102 to abut against a recessed face 104 of a corresponding recess 102. By engaging with the recesses 102, the second sections 232, 332 of the touch portions 23, 33 are prevented from moving in a direction parallel to the longitudinal axis of the transverse beam. Each arc-shaped second section 232, 332 protrudes below the bottom face (not labeled) of the transverse beam 10.

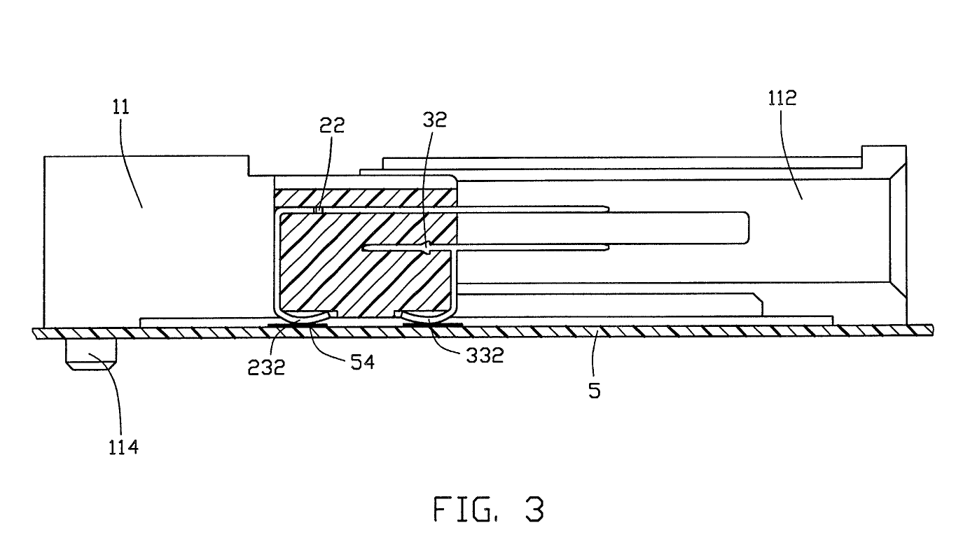

Referring to FIG. 3, the projections 114 of the housing 1 are inserted into a pair of positioning holes 51 defined in the printed circuit board 5 whereby the fastening holes 43 align with through holes 52 bored into the printed circuit board 5. The screws 41 extend through the fastening holes 43 and the through holes 52 to fasten with corresponding nuts 42, thereby fixing the electrical card connector to the printed circuit board 5. At the same time, the second sections 232, 332 of the terminals 2, 3 resiliently make electrical contact with electrical pads 54 mounted on the printed circuit board 5 to achieve electrical connection between the electrical card connector and the printed circuit board 5.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. An electrical card connector for mating with an electrical card and mounting to a printed circuit board, a plurality of electrical pads being provided on the printed circuit board, comprising:
an insulative housing comprising a transverse beam and a pair of arms formed on opposite ends of the transverse beam, a receiving space defined between the transverse beam and both arms, the transverse beam defining a plurality of passageways therein;
a plurality of terminals, each comprising a fixing portion fixed in a corresponding passageway, a contacting portion extending into the receiving space for mating with the electrical card, and a touch portion extending from the fixing portion and protruding beyond a bottom face of the transverse beam;
a fastening device for fastening the electrical card connector to the printed circuit board;
wherein, when the electrical card connector is fastened to the printed circuit board, the touch portion of each terminal resiliently makes electrical contact with a corresponding electrical pad of the printed circuit board.

2. The electrical card connector as claimed in claim 1, wherein the housing further defines a plurality of recesses in a bottom face of the transverse beam and each recess aligns with a corresponding passageway, the touch portion of each terminal abuts against a recessed face of a corresponding recess thereby preventing the touch portion from moving in a direction parallel to the longitudinal axis of the transverse beam.

3. The electrical card connector as claimed in claim 1, wherein the touch portion of each terminal comprises a first section perpendicular to the fixing portion and a second section parallel to the fixing portion.

4. The electrical card connector as claimed in claim 3, wherein the second sections of the touch portions of the terminals each have an arced shape and are resiliently bendable.

5. The electrical card connector as claimed in claim 1, wherein the fastening device comprises a pair of screws and a pair of nuts, and a pair of fastening holes are defined through the arms of the housing, and the screws extend through the fastening holes and through a pair of through holes defined in the printed circuit board to engage with the corresponding nuts, thereby fastening the electrical card connector to the printed circuit board.

6. The electrical card connector as claimed in claim 1, wherein a pair of channels is defined in the arms of the housing, the channels communicating with the receiving space for guiding the electrical card mating with the electrical card connector.

7. The electrical card connector as claimed in claim 1, wherein a pair of projections is formed on a bottom face of each arm for extending into a pair of positioning holes defined in the printed circuit board for positioning the electrical card connector on the printed circuit board.

8. An electrical connector comprising:
an insulative housing defining opposite first and second faces thereon;
upper and lower rows of terminals disposed in the housing; wherein
each of the terminals in the upper row attached to the first face of the housing with a fixing portion and successively a contact portion horizontally extending from the first face to the second face through the housing and exposed to the second face with a predetermined first distance, and with a solder portion downwardly extending along the first face; and
each of the terminals in the lower row attached to the second face of the housing with a contact portion horizontally extending from the second face away from the housing with a predetermined second distance, and with a fixing portion extending from the second face toward the first face and embedded within the housing, and with a solder portion downwardly extending along the second face.

9. The connector as claimed in claim 8, wherein the solder portion of the terminal in the upper row extends from the corresponding fixing portion.

10. The connector as claimed in claim 8, wherein the solder portion of the terminal in the lower row extends between the corresponding fixing portion and contact portion.

11. The connector as claimed in claim 8, wherein said solder portions of the terminals in both upper and lower rows are of J-shape.

12. The connector as claimed in claim 8, wherein said first distance is equal to said second distance.

13. An electrical connector comprising:
an insulative housing defining opposite first and second faces thereon;
upper and lower rows of terminals disposed in the housing; wherein
each of the terminals in the upper row including a fixing portion and successively a contact portion horizontally extending out of the second face and exposed with a predetermined distance, and with a J-shaped solder portion downwardly extending from the fixing portion; and
each of the terminals in the lower row including a contact portion horizontally extending from the second face away from the housing with said predetermined distance, and with a fixing portion extending from the second face toward the first face and embedded within the housing, and with a J-shaped solder portion downwardly extending between said contact portion and said fixing portion.
